(19) United States
(12) Patent Application Publication
(10) Pub. No.: US 2008/0156441 A1
(43) Pub. Date: Jul. 3, 2008

(54) PLASMA PROCESSING APPARATUS AND ELECTRODE PLATE, ELECTRODE SUPPORTING BODY, AND SHIELD RING THEREOF

(75) Inventors: Masahiro Ogasawara, Nirasaki-shi (JP); Kazuya Kato, Nirasaki-shi (JP); Toshifumi Nagaiwa, Dresden (DE); Kosuke Imafuku, Nirasaki-shi (JP); Koichi Kazama, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/040,523

(22) Filed: Feb. 29, 2008

Related U.S. Application Data
(62) Division of application No. 10/383,605, filed on Mar. 10, 2003.
Application No. 10/383,605 is a continuation of application No. PCT/JP01/07985, filed on Sep. 14, 2001.

(30) Foreign Application Priority Data
Sep. 14, 2000 (JP) 2000-279453
Sep. 26, 2000 (JP) 2000-291717
Jul. 5, 2001 (JP) 2001-204884

(51) Int. Cl. H01L 21/306

(52) U.S. Cl. 156/345.43

(57) ABSTRACT

In a plasma apparatus 1 for performing plasma processing on a substrate W to be processed, an upper electrode 21, which faces opposite a susceptor 5 which is a lower electrode, has an electrode supporting body 22 and an electrode plate 23. In the center on the side of the electrode supporting body at the boundary between the two, a hollow 62, the dimensions of which are determined such that a resonance is generated at a frequency of supplied high-frequency electric power and an electric field orthogonal to the electrode plate 23 is generated inside, is provided. Furthermore, a shield ring which surrounds the electrode plate 23 has a shape in which the lower surface is in the same level as the electrode plate 23, and it is made of a material that is not easily eroded by the plasma. By this, processing small features becomes possible with uniform distribution of plasma and in less degradation due to change over time.

### CROSS REFERENCE

This application is a division of and is based upon and claims the benefit of priority under 35 U.S.C. §120 for U.S. Ser. No. 10/383,605, filed Mar. 10, 2003, which is a continuation of PCT/JP01/07985, filed Sep. 14, 2001, and claims the benefit of priority under 35 U.S.C. §119 from Japanese Patent Application Nos. 2000-279453, filed Sep. 14, 2000, JP 2000-291717, filed Sep. 26, 2000, JP 2001-204884, filed Jul. 5, 2001.

### TECHNICAL FIELD

The present invention relates to a plasma processing apparatus, and electrodes, electrode supporting body, and shield ring thereof.

### RELATED PRIOR ART

Plasma apparatuses have been used from the past, for example in the semiconductor fabrication process, as apparatuses for example to form contact holes by etching insulation films on the surfaces of semiconductor wafers. Among them, in particular, parallel flat-plate type plasma apparatuses in which the electrodes are placed at the upper and lower positions in the processing chamber have become the mainstream of plasma apparatuses since they are excellent in uniformity, they are capable of processing of large diameter wafers, and the structures of the apparatuses also are comparatively simple.

A conventional parallel flat-plate type etching apparatus, for example as disclosed in Japanese Patent Application No. 2000-116304, is constituted such that the electrodes are placed vertically opposite each other inside the processing chamber, a semiconductor wafer as a substrate to be processed is placed on the lower electrode, an etching gas is introduced into this processing chamber and at the same time high-frequency electric power is supplied to the lower electrode to generate a plasma between the upper and lower electrodes, and an insulation film on the semiconductor wafer is etched by the etchant constituents which are produced by dissociation of the etching gas.

FIG. 3 is a drawing schematically showing the upper electrode and shield ring in Japanese Patent Application No. 2000-116304. As shown in FIG. 3, the upper electrode 121 has an electrode plate 123, an electrode supporting body 122 placed on top of that, and a hollow 162 provided at the boundary between the two. Furthermore, the periphery of the upper electrode 121 has a structure, in which it is fixed to the upper part of the processing chamber of the plasma apparatus by an insulating material 125, and a shield ring 155 is placed on the lower part of the insulating material 125.

Thus, in order to respond to the demands for miniaturization of processing, improvement of processing rate, and uniformity of processing, the shield ring 1557, which protrudes from the upper electrode surface toward the lower electrode, is provided on the periphery of the upper electrode 121 to confine the plasma, and furthermore, the hollow

However, it was learned that a problem arises in the technology disclosed in Japanese Patent Application No. 2000-116304, in which the protruding part of the shield ring which protrudes toward the lower electrode, which works for confining the plasma, is worn down due to change over time and the distribution of the plasma changes.

Also, FIG. 16 is a drawing schematically showing a different form of the upper electrode 421 in the conventional etching apparatus. As shown in FIG. 16, the upper electrode 421 has an electrode plate 423 and an electrode supporting body 422 placed on top of that. The electrode supporting body 422 is constituted, for example, with aluminum. The electrode supporting body 422 supports the electrode plate 423 and also functions as a cooling plate for the electrode plate 423. The electrode plate 423 is attached to the electrode supporting body 422 by screws 460 so as to be removable, and it is removed for maintenance, and the like. The electrode plate 423 is made, for example, using silicon, etc.

When plasma processing is performed using an etching apparatus having the conventional upper electrode 421, because the temperature inside the processing chamber rises as the processing gas is introduced into the apparatus which is drawn to a high vacuum and high-frequency electric power is applied, it sometimes caused fusion-adhesion at the boundary surface between the aluminum material of the electrode supporting body 422 and the silicon material of the electrode plate 423.

FIG. 17 is a sectional view schematically showing the state in which fusion-adhesion was caused after using the conventional upper electrode 421 for etching processing, and FIG. 18 is a drawing conceptually showing the electrode plate 423 re-moved from the electrode supporting body 422, which incurred the fusion-adhesion. As shown in FIG. 17 and FIG. 18, an uneven surface including aluminum erosions 165 and silicon fusion-adhesions 167 occurs at the boundary surface between the electrode supporting body 422 and the electrode plate 423, and the surface evenness is lost.

Incidentally, when the electrode plate 423, which is removed for maintenance such as cleaning of the etching apparatus, is again attached to the electrode supporting body 422, it is unavoidable that the positional relationship of the uneven surfaces differs from that before removal. Therefore, when fixing with screws 460 at the time of reattaching, there was a problem that stress concentrated at the convex portions of the electrode supporting body 422 and the electrode plate 423, and it caused cracking of the electrode-plate 433.

The present invention was created in consideration of the above problems of the conventional plasma apparatuses, and the purpose of the present invention is to provide a new and improved plasma processing apparatus, in which the distribution of the plasma is uniform, there is little degradation due to change over time, and processing small features is possible, and an electrode plate, electrode supporting body, and shield ring thereof.

Also, another purpose of the present invention is to provide a plasma processing apparatus having an electrode plate with which fusion-adhesion of the silicon and the aluminum is prevented and cracking is not caused when reattaching, and an electrode plate and electrode supporting body thereof

### DISCLOSURE OF THE INVENTION

In order to solve the above problems, according to the present invention, a plasma processing apparatus, comprising: a processing chamber; a first electrode on which a body to be processed can be placed inside the processing chamber; a second electrode which is placed facing opposite the first electrode inside the processing chamber; a processing gas supply system which is capable of supplying a processing gas into the processing chamber; an exhaust system which is capable of vacuum-exhausting the processing chamber; and a high-frequency electric power supply system which applies high-frequency electric power to at least one of the first and second electrodes to make the processing gas into a plasma and performs prescribed plasma processing on the body to be processed, wherein: the second electrode comprises an electrode plate which is provided facing opposite the first electrode and is constituted with a conductor or a semiconductor, a conductive supporting body which is provided on the surface of the electrode plate on the opposite side to that facing the inside of the processing chamber and supports the electrode plate, and a hollow part which is provided in the center of the supporting body; a shield ring which is in roughly the same surface level as the electrode plate is provided on the periphery of the second electrode inside the processing chamber; and the above shield ring, supporting body, and electrode plate are provided.

Here, it is desirable that the resistance value of the shield ring is lower than the resistance value of the electrode plate. For example, if the resistance value of the shield ring is 1 to 10 Ωcm, the resistance value of the electrode plate is set to 65 to 85 Ωcm. The shield ring and the electrode plate can be constituted with the same material. Silicon can be used for that material. It is desirable that the outer diameter of the electrode plate is larger than the outer diameter of the first electrode. Also, it may be a plasma processing apparatus with an electrode plate in which a hollow part is provided in the center of the electrode plate on the side of the supporting body, without a hollow part being provided in the supporting body, or also a plasma processing apparatus having an electrode body and supporting body in which hollows are not provided.

According to such constitution, a new and improved plasma processing apparatus in which the distribution of the plasma is made uniform by controlling it such that the electric field at the center part becomes strong, there is little degradation due to change over time by adopting the shield ring with the surface in the same level as the electrode surface, and processing small features is possible, and the electrode plate, electrode supporting body, and shield ring thereof, can be provided.

Also, a plasma processing apparatus, comprising: a processing chamber; a first electrode on which a body to be processed can be placed inside the processing chamber; a second electrode which is placed facing opposite the first electrode inside the processing chamber; a processing gas supply system which is capable of supplying a processing gas into the processing chamber; an exhaust system which is capable of vacuum-exhausting the processing chamber; and a high-frequency electric power supply system which applies high-frequency electric power to at least one of the first and second electrodes to make the processing gas into a plasma and performs prescribed plasma processing on the body to be processed, wherein: the second electrode consists of a supporting body and an electrode plate on which a surface facing opposite said body to be processed is formed; an insulation film is formed on at least one of the surfaces of contact between the supporting body and the electrode plate; and the supporting body and the electrode plate are provided.

The thickness of the insulation film formed on the supporting body or the electrode plate should be less than or equal to 50 μm, preferably 10 to 30 μm. The supporting body can be constituted with aluminum and the electrode plate with silicon. The insulation film on the aluminum surface can be made as a rare-earth oxide or an aluminum compound, and the insulation film on the silicon surface can be made as a silicon compound. According to such constitution, a plasma processing apparatus having an electrode that does not incur cracking even when reattaching and having excellent durability, and the electrode plate and electrode supporting body thereof, are provided.

### BRIEF DESCRIPTION OF THE DRAWINGS

FIG. 1 is a sectional view showing the constitution of the plasma apparatus I pertaining to one preferred embodiment of the present invention.

FIG. 2 is a sectional view schematically showing the upper electrode 21 and the shield ring 55 pertaining to the first preferred embodiment.

FIG. 3 is a sectional view schematically showing the upper electrode and the shield ring in a conventional plasma apparatus.

FIG. 4 is a diagram showing the etching rate in a plasma apparatus using a conventional shield ring 155.

FIG. 5 is a diagram showing the etching rate in a plasma apparatus using a shield ring 55.

FIG. 6 is a rough sectional view showing the surroundings of a shield ring 255.

FIG. 7 is an enlarged view of part A in FIG. 6.

FIG. 8 is a rough sectional view showing the surroundings of a conventional shield ring 155.

FIG. 9 is an enlarged view of part B in FIG. 8.

FIG. 10 is a diagram showing the rates of decrease of the etching rate due to change over time.

FIG. 11 is a diagram showing a comparison of the amount of change of etching rate within the surface of a wafer.

FIG. 12 is a diagram showing the change of pressure over time on a wafer.

FIG. 13 is a sectional view showing an upper electrode 221 and a shield ring 55.

FIG. 14 is a sectional view showing the constitution of the plasma apparatus 100 pertaining to the present preferred embodiment.

FIG. 15 is a sectional view schematically showing an upper electrode 321.

FIG. 16 is a drawing schematically showing the upper electrode 421 in a conventional plasma apparatus.

FIG. 17 is a sectional view schematically showing the state in which fusion-adhesion caused after using a conventional upper electrode 421 in etching processing.

FIG. 18 is a drawing conceptually showing an electrode plate 423 removed from an electrode supporting body 422 and having incurred fusion-adhesions.

FIG. 19 is a sectional view showing an upper electrode 521.

### DESCRIPTION OF THE PREFERRED EMBODIMENTS

The preferred embodiments of the plasma processing apparatuses pertaining to the present preferred embodiments, and the electrode plates, electrode supporting bodies, and shield rings thereof, are explained in detail below while referring to the attached drawings.

### Preferred Embodiment 1

### (1) Constitution of the Processing Apparatus

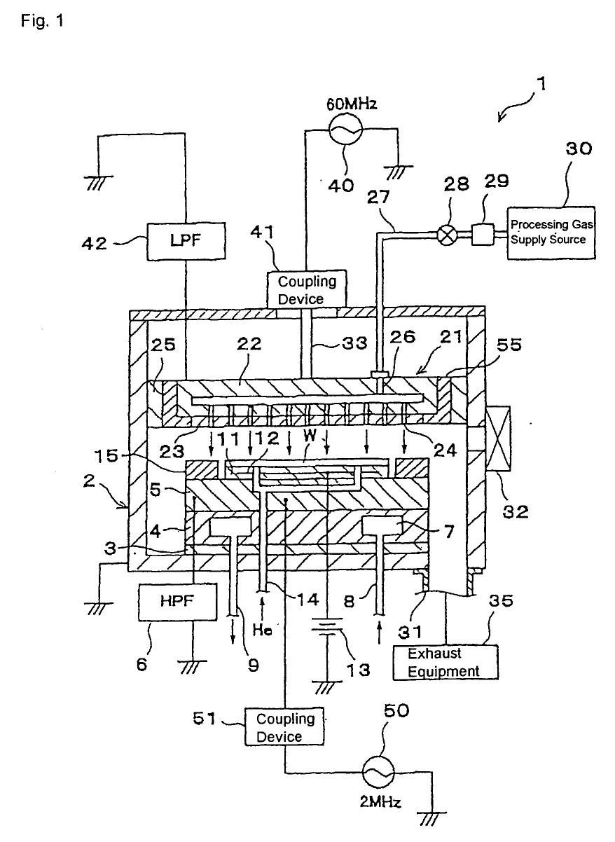

FIG. 1 is a sectional view showing the constitution of the plasma apparatus 1 pertaining to the present preferred embodiment.

The processing chamber 2 in the plasma apparatus 1 is formed as a cylindrical processing container, for example consisting of aluminum, or the like, treated with oxidized alumite, and it is grounded.

An insulating supporting plate 3 consisting of a ceramic, or the like, is provided on the bottom part inside the processing chamber 2, and a roughly round columnar susceptor supporting table 4 for placing a substrate to be processed, for example a semiconductor wafer W having an 8-inch diameter, is provided on the top of this insulating supporting plate 3. A susceptor 5 constituting the lower electrode is further provided on the top of the susceptor supporting table 4, and a high pass filter (HPF) 6 is connected.

A heat exchanging chamber 7 is provided inside the susceptor supporting table 4, and it is constituted such that a heat exchanging medium circulates from the outside via a heat exchanging medium intake pipe 8 and a heat exchanging medium exhaust pipe 9 so as to be capable of keeping the semiconductor wafer W at a prescribed temperature via the susceptor 5. Also, it is constituted such that such temperature is automatically controlled by a temperature sensor (not illustrated) and a temperature control mechanism (not illustrated).

Also, an electrostatic chuck 11 for adhering and holding the semiconductor wafer W is provided on the top of the susceptor 5. This electrostatic chuck 11 has a structure in which, for example, a conductive thin film electrode 12 is sandwiched from above and below by polyimide resins, and when, for example, 1.5 kV voltage is applied to the electrode 12 from a DC power supply 13 which is placed outside the processing chamber 2, the wafer W comes to be adhered and held on the top surface of the electrostatic chuck 11 by the coulomb force thereof. Of course, not depending on such electrostatic chuck, it also may be constituted such that the perimeter edges of the wafer W are pressed by a mechanical clamp to hold the wafer W on the top of the susceptor 5.

Furthermore, a gas channel 14 for supplying, for example He gas, or the like, to the underside of the semiconductor wafer W, is formed in the insulating plate 3, susceptor supporting table 4, susceptor 5, and electrostatic chuck 11, and the semiconductor wafer W is kept at a prescribed temperature with the heat transfer medium of this He gas, or the like.

A roughly annular focus ring 15 is provided on the periphery on the top of the susceptor 5 so as to surround the electrostatic chuck 11. The focus ring 15, for example, consists of conductive silicon, and it has the function of effectively making ions in the plasma fall onto the semiconductor wafer W.

An upper electrode 21 is supported on the upper part inside the processing chamber 2 with an insulating member 25 and a shield ring 55. The upper electrode 21 has an electrode supporting body 22, for example consisting of aluminum of which the surface is treated with alumite, and an electrode plate 23 having a large number of ejection holes 24, which faces opposite and parallel to the susceptor 5. The susceptor 5 and the upper electrode 21 are separated, for example by about 10 to 60 mm. The detailed constitutions of the upper electrode 21 and the shield ring 55 are described later.

A gas inlet port 26 is provided on the electrode supporting body 22, and it is connected to a gas supply pipe 27. Furthermore, it is connected to a processing gas supply source 30 via a valve 28 and a mass flow controller 29, and an etching gas and other processing gases are introduced into the processing chamber 2.

As processing gases, gases containing a halogen element, for example such as fluorocarbon gas (CₓF_{y}) and hydrofluorocarbon gas (CₚH_{q}Fᵣ), can be used.

An exhaust pipe 31 which passes to an exhaust equipment 35 such as a vacuum pump is connected to the lower part of the processing chamber 2. The exhaust equipment 35 has a vacuum pump such as a turbo-molecular pump, and it is possible to draw a gas inside the processing chamber 2 to an arbitrary degree of reduced pressure, for example 10 mTorr to 100 mTorr.

A gate valve 32 is provided on the side wall of the processing chamber 2, and it is made so as to allow a wafer W to be conveyed to and from an adjacent load lock chamber (not illustrated) when the gate valve 32 is in the open state.

Next, the high-frequency electric power supply system of this plasma apparatus I is explained. First, it is constituted such that electric power from a first high-frequency electric power supply 40, which outputs high-frequency electric power having a frequency of, for example, 27 to 150 MHz, is supplied to the upper electrode 21 via a coupling device 41 and a feed rod 33. Also, a low pass filter (LPF) 42 is connected to the upper electrode 21.

By applying a high frequency in this way, a plasma that is in a desirable state of dissociation and has high density can be created inside the processing chamber 2, and plasma processing under low-pressure conditions becomes possible. In the present preferred embodiment, a high-frequency electric power supply having 60 MHz is used as the high-frequency electric power supply 40.

On the other hand, it is constituted such that electric power from a high-frequency electric power supply 50, which outputs high-frequency electric power having a frequency of, for example, about 800 KHz to 4 MHz, is supplied to the susceptor 5 which serves as the lower electrode via a coupling device 51. By applying a frequency in such range, it is possible to subject the semiconductor wafer W to the proper ion action without causing damage.

### (2) Constitution of the Upper Electrode and the Shield Ring

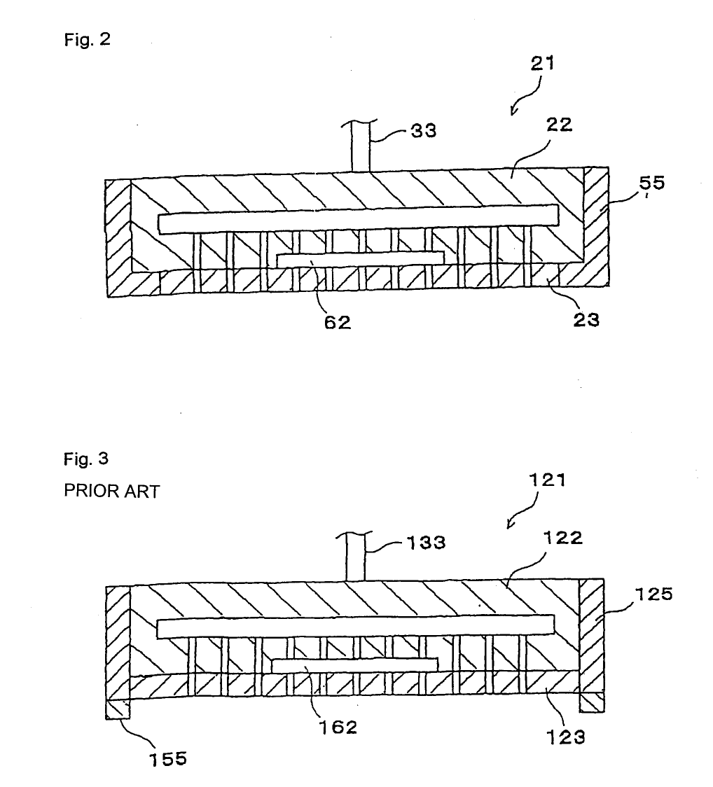

Next, the constitutions of the upper electrode 21 and the shield ring 55 are explained in detail. FIG. 2 is a sectional view schematically showing the upper electrode 21 and the shield ring 55.

As shown in FIG. 2, a hollow 62 is provided in the center of the electrode supporting body 22, which is provided on the top of the electrode plate 23, so as to be adjacent to the electrode plate 23. The dimensions (diameter and thickness) of this hollow 62 are determined such that a resonance occurs at a frequency of the high-frequency electric power supplied to the upper electrode 21 and an electric field orthogonal to the electrode plate 23 occurs inside of it, that is, such that the thickness from the electrode plate surface at the part where the high-frequency electric power is supplied to the electrode plate 23, that is, the skin depth δ expressed in the formula (1) below, becomes greater than the thickness of the electrode plate 23.

δ=(2ρ/ωμ)^{1/2} (1)

where, (ω: angular frequency of the high-frequency electric power (2πf(f=frequency)), ρ: specific resistance of the electrode plate, (μ: permeability of the electrode plate.

Thus, when a resonance occurs inside the hollow 62 and an electric field orthogonal to the electrode plate 23 occurs, the electric field of the hollow 62 and the electric field of the electrode plate 23 are added, and the electric field at the center of the electrode immediately beneath the hollow 62 in the electrode plate 23 can be controlled by the electric field of the hollow 62. Therefore, a more uniform plasma distribution can be realized.

Also, as shown in FIG. 3, a conventional shield ring 155 was constituted protruding on the lower part which is the side of the semiconductor wafer, in order to obtain the effect of confining the plasma by constituting a gap shorter than the distance between the upper electrode and the semiconductor wafer. Also, it usually was formed with quartz, and because it protruded on the lower part, it was easily worn down by the plasma.

Therefore, the shield ring 55 pertaining to the present preferred embodiment is constituted with the lower part in the same level as the bottom surface of the electrode plate 23 as shown in FIG. 2. The resistance value is set lower than the resistance value of the electrode plate 23. Also, it may be made with the same material as the electrode plate 23. Silicon is applicable as the material used for the electrode plate 23 and the shield ring 55.

Also, in considering the electric field distribution between the lower electrode and the upper electrode, the resistance values of the shield ring 55 and the electrode plate 23 are properly 1 to 10 Ωcm and 65 to 85 Ωcm, respectively.

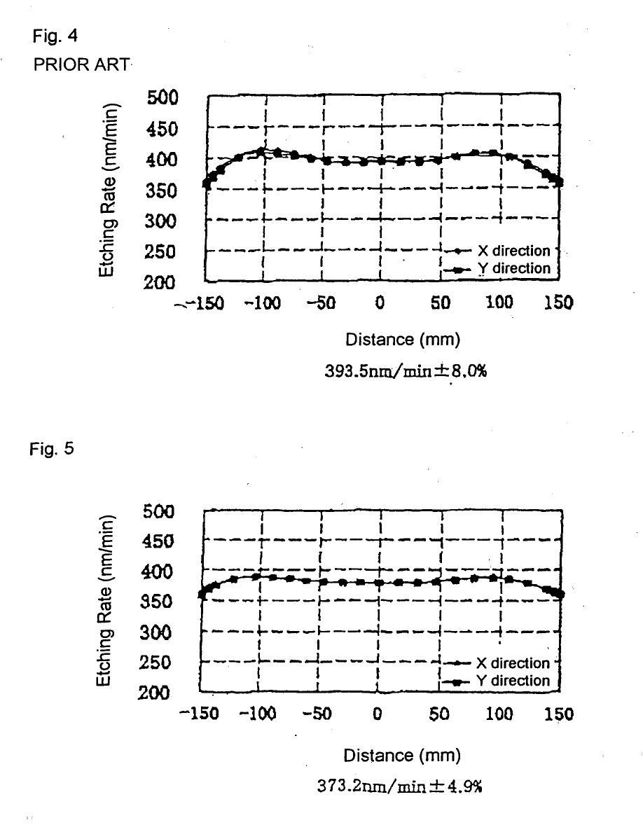

FIG. 4 is a diagram showing the etching rate in a plasma apparatus using the conventional shield ring 155, and FIG. 5 shows the etching rate in a plasma apparatus using the shield ring 55 pertaining to the present preferred embodiment.

Both diagrams of FIG. 4 and FIG. 5 are the results of having measured the average etching rates (nm/min.) with respect to two orthogonal directions (X and Y directions) to the distance (mm) from the center of the semiconductor wafer when processing was performed for the same time under the same conditions except for the materials and structures of the shield rings. Here, the shield ring 155 is made of quartz, and the shield ring 55 is made of silicon having a resistance value of about 2Ω.

As shown in FIG. 4 and FIG. 5, when the conventional shield ring 155 is used, decreases of the etching rate are clearly seen in the range more than the distance from the center is 100 mm. On the other hand, because a high-frequency current flowing in the low-resistance shield ring 55 becomes greater than when the higher-resistance shield ring 155 is used, the plasma density around that part rises, and the uniformity of the plasma over the entire surface of the semiconductor wafer can be improved.

Furthermore, owing to the material and structure of the conventional shield ring 155, the protruding part is always exposed to the plasma and changes over time to be worn down, and it can be considered that it becomes to no longer exhibit the essential effect of confining the plasma. It is self-evident that this trend becomes more prominent if processing is repeated a plurality of times.

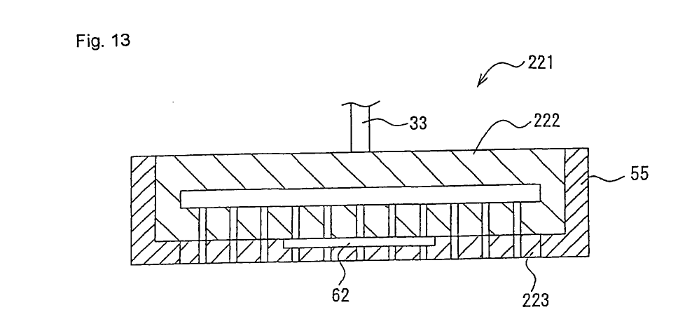

Also, in the present preferred embodiment, control of the electric field is possible by the hollow 62 provided in the supporting body 22 at the top of the electrode 23, and the distribution of the plasma is kept enough uniform. Also, this hollow 62 can obtain the same effect even when constituted being provided in the electrode plate 223, as in the upper electrode 221 shown in FIG. 13. Therefore, by adopting the shield ring 55 in combination, a more highly reliable plasma apparatus I can be realized.

Conversely, because the distribution of the plasma is kept enough uniform by adopting the shield ring 55, the same effect can be obtained even when constituted without the hollow 62 being provided at the upper part of the electrode plate 23 and the supporting body 22. Furthermore, in order to make the plasma distribution uniform, it is useful also to constitute the diameter of the electrode plate 23 larger than the diameter of the susceptor 5 which is the lower electrode.

### Preferred Embodiment 2

Next, the shield ring pertaining to the second preferred embodiment is explained. Because a plasma processing apparatus which is furnished with the shield ring pertaining to the second preferred embodiment is substantially the same as the plasma processing apparatus 1, the explanation is omitted.

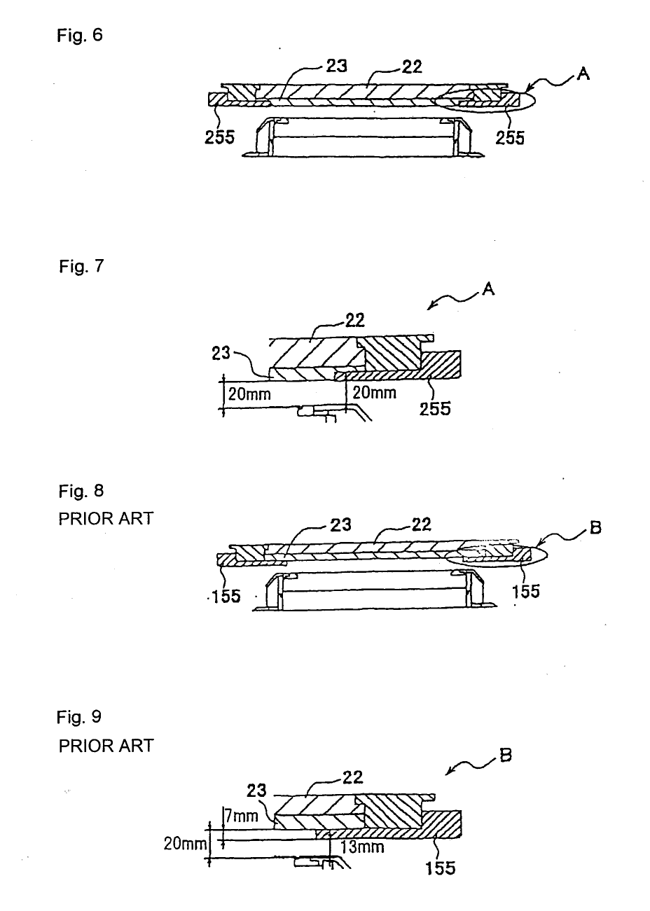

FIG. 6 is a rough sectional view showing the surroundings of the shield ring 255 pertaining to the present preferred embodiment. FIG. 7 is an enlarged view of the part A in FIG. 6, FIG. 8 is a rough sectional view showing the surroundings of the conventional shield ring 155, and FIG. 9 is an enlarged view of the part B in FIG. 8.

As shown in FIG. 8 and FIG. 9, with the conventional shield ring 155, for example when the distance between the wafer W and the electrode plate 23 of the upper electrode is 20 mm, a step for example protruding about 7 mm downward arises, and the distance from the surface of the wafer is made narrower as 13 mm.

However, when there is such a step, the surface of the shield ring 155 is worn down as the time of exposure to the plasma becomes longer, and the gas pressure on the top of the wafer W is lowered. Therefore, the etching rate is lowered, and the etch stop margin of the contact holes is changed. In order to mitigate this change over time, as shown in FIGS. 6 and 7, the shield ring 255 is constituted in the same level as the lower surface of the electrode plate 23.

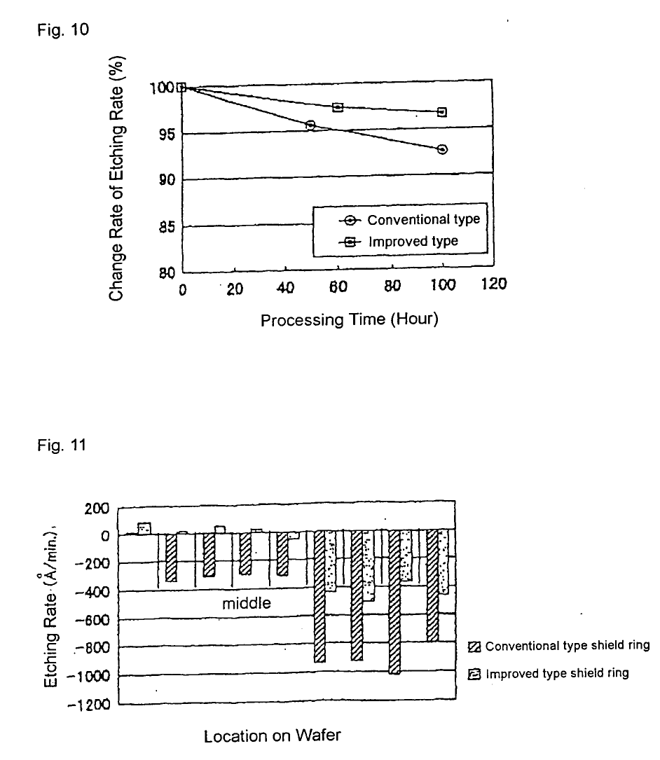

FIG. 10 is a diagram showing the rate of decrease of the etching rate due to change over time, and FIG. 11 is a diagram showing a comparison of the amount of change of the etching rate within the surface of a wafer. These are results of having performed plasma processing by supplying electric power of 27, 12 MHz from the high-frequency electric power supply 40 for the upper electrode and 800 KHz from the high-frequency electric power supply 50 for the lower electrode in the plasma processing apparatus I pertaining to the first preferred embodiment.

The electrode plate 23 is made of single crystalline silicon and its resistance is I to 10 Ωcm. The shield ring 155 (conventional type) and the shield ring 255 (improved type) both are made of quartz and have insulating property (about 1016 Ωcm). As other processing conditions, optimized ones for the respective shield rings were used.

That is, for the conventional type shield ring 155, they are pressure 40 mTorr, electric power supplied to the upper electrode/electric power supplied to the lower electrode=2000/1400 W, distance between the electrode plate 23 and wafer W=17 mm, processing gas flow amount C₄F₈/Ar/O₂=21/510/11 sccm, wafer center underside cooling gas pressure/wafer edge underside cooling gas pressure=10/35 Torr, and lower electrode temperature/upper electrode temperature/processing chamber side wall temperature=−20/30/50° C.

For the improved type shield ring 255, they are pressure 50 m Torr, electric power supplied to the upper electrode/electric power supplied to the lower electrode=2000/1400 W, distance between the electrode plate 23 and wafer W=17 mm, processing gas flow amount C₄F₈/Ar/O₂=21/450/10 sccm, wafer center underside cooling gas pressure/wafer edge underside cooling gas pressure=12/25 Torr, and lower electrode temperature/upper electrode temperature/processing chamber side wall temperature=0/30/50° C.

In FIG. 10, the horizontal axis shows the plasma processing time, and the vertical axis shows the rate of change of the etching rate. Whereas the decrease of the etching rate after 100 hours of the plasma processing time was about 8% with the conventional step type shield ring 155, it could be made to about 4% when the improved flat type shield ring 255 without the step with the electrode plate 23 was used.

In FIG. 11, the rate of change of the etching rate after 100 hours of the plasma processing at the center, intermediate part, and edge part on the surface of the wafer W is shown by the vertical axis. Thus, with the improved type shield ring 255, the amount of change at the center part and the intermediate part of the wafer became almost zero, and at the edge part, it was reduced to about 500 A/min., whereas it was about 1000 A/min. with the conventional type shield ring 155.

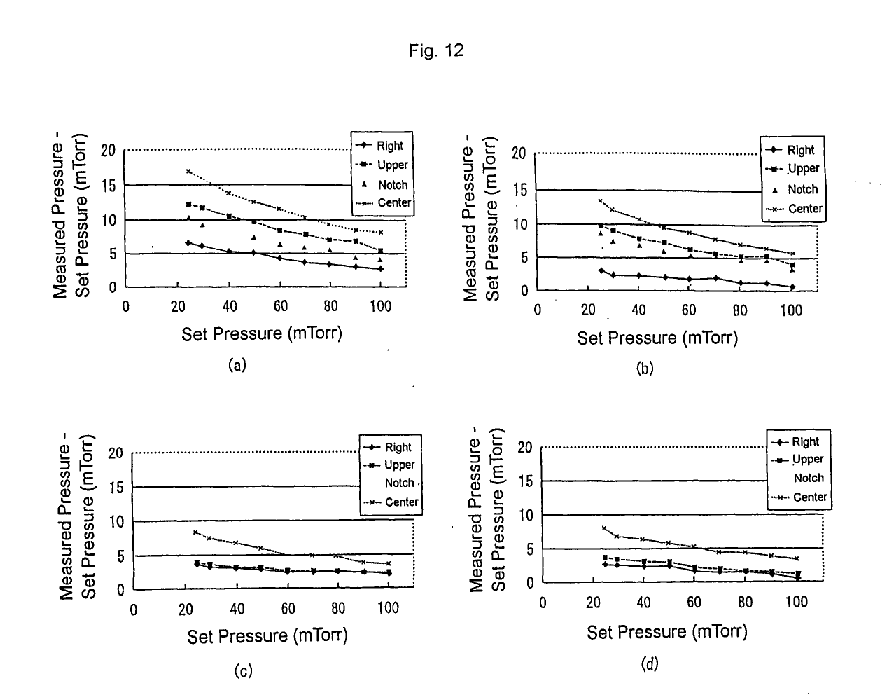

Next, the reason why the rate of change of the etching rate was decreased as described above is explained using FIG. 12. FIG. 12 is a diagram showing the change of pressure over time on a wafer. FIGS. 12(a) and (b) respectively are the initial state and the state after 100 hours of the plasma processing using the conventional type shield ring 155, and FIGS. (c) and (d) respectively are the initial state and the state after 100 hours of the plasma processing using the improved type shield ring 255. The horizontal axis shows the set pressure, and the vertical axis shows the difference between the pressure measured at respective positions (right, top, notch, and center) on the wafer and the set pressure.

The wear of the shield ring was 2 mm/100 hours both for the conventional type and the improved type. However, in the conventional type shield ring 155, the difference between the set pressure and the measured pressure is changed between before and after the processing. Also, the absolute value of that pressure difference is greater than the improved type.

It is believed that this is because the step of the shield ring 155 causes a pressure variation. When the pressure difference is different according to the locations on the wafer, the etch stop margin of contact holes becomes no longer uniform, and there is a risk that the yield may be degraded. Also, it is understood that the above-described decrease of the etching rate and the change of etch stop margin of machined holes are caused by the change of pressure over time.

As explained in detail above, according to the shield ring pertaining to the second preferred embodiment, a high-performance film formation processing apparatus which is capable of finer processing can be provided, by making the gas pressure on the wafer uniform, also by mitigating the change of gas pressure over time on the wafer which is due to wearing of the shield ring after plasma processing, reducing the decrease of etching rate due to the change over time, and improving the etch stop margin of machined holes and their uniformity inside the wafer.

Of course, it can be used together with the upper electrode 21 or 221 pertaining to the first preferred embodiment in the plasma processing apparatus.

Also, for example, the shape of the shield ring is not limited to the example described in the present preferred embodiment, and it doesn't matter even if it is another shape as long as the lower surface is in roughly the same level as the upper electrode. Also, the case in which a semiconductor wafer was used as a substrate to be processed and this was subjected to etching was shown, but an object for processing also may be another substrate, for example such as a substrate for a liquid crystal display, and the plasma processing as well is not limited to etching, and it also may be other processing such as sputtering or CVD.

### Preferred Embodiment 3

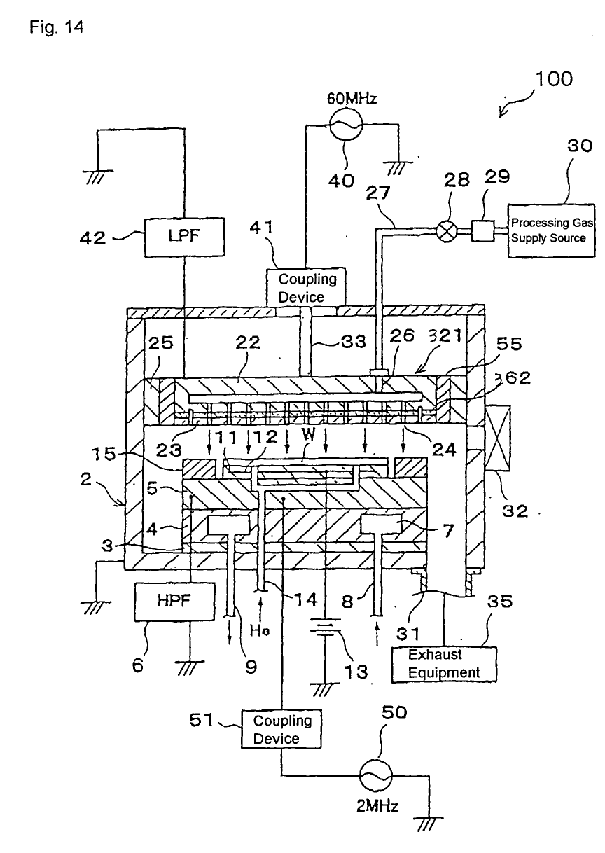

FIG. 14 is a sectional view showing the constitution of the plasma apparatus 100 pertaining to the third preferred embodiment of the present invention. Because the constitution of the plasma apparatus 100 is substantially the same as that of the plasma processing apparatus I, the explanation is omitted.

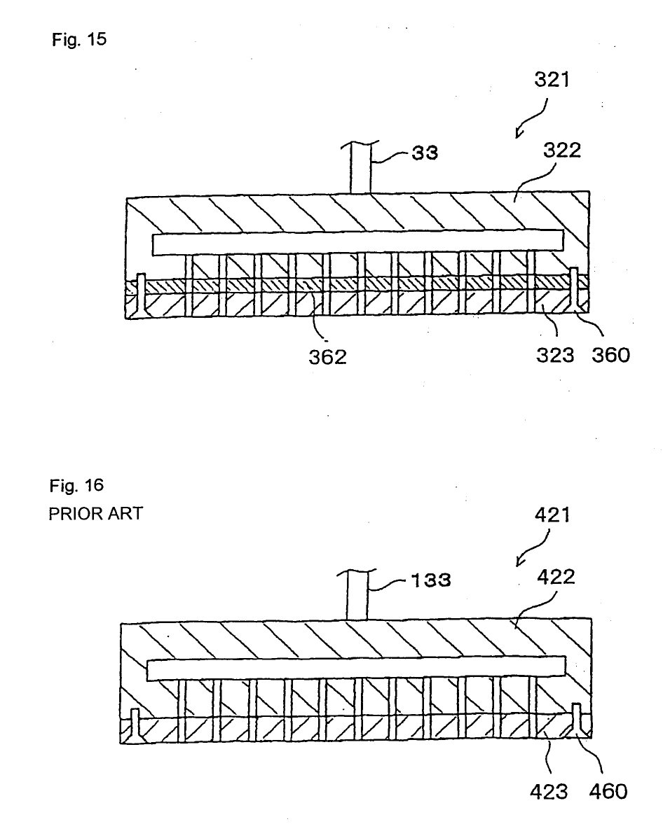

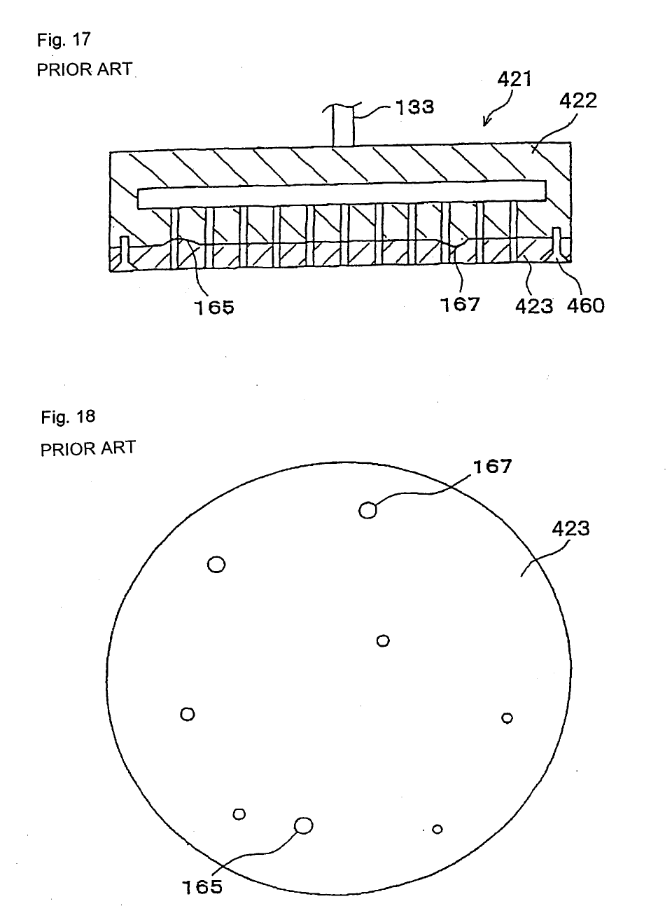

Next, the constitution of the upper electrode 321 is explained in detail. FIG. 15 is a sectional view schematically showing the upper electrode 321 pertaining to the present preferred embodiment. The upper electrode 321 has an electrode supporting body 322, electrode plate 323, and insulation film 362, etc.

The electrode supporting body 322 supports the electrode plate 323, and at the same time, it transfers high-frequency electric power, also it keeps the temperature distribution of the electrode plate 323 constant with its high thermal conductivity, and in addition it functions as a cooling material to prevent rise of temperature. The electrode plate 323 is fixed to the electrode supporting body 322 with screws 360 so as to be removable.

Conventionally, the electrode supporting body and the electrode plate were constituted so as to be directly in contact, considering the etching rate and the thermal diffusivity. However, in the present preferred embodiment, a thin insulation film 362 is formed at least on one side of the boundary surface between the electrode supporting body 322 and the electrode plate 323. The electrode supporting body 322 is constituted with aluminum, and when the insulation film 362 is provided on its surface, a rare-earth oxide or aluminum compound, or the like, can be used as the material of the insulation film 362. As rare-earth oxide, for example, Y₂O₃ melt-spray film, and as aluminum compound, for example, alumite film, Al₂O₃ melt-spray film, and the like, are applicable.

Also, the electrode plate 323 is constituted with silicon, and when the insulation film 362 is provided on its surface, a silicon compound can be used as the material of the insulation film 362. The silicon compounds are, for example, SiO₂, Si₃N₄, and the like. By this, because direct contact between the aluminum of the electrode supporting body 322 and the silicon of the electrode plate 323 is avoided, fusion-adhesion can be prevented. Also, by making the thickness of the insulation film 362, for example less than or equal to 50 μm, a sufficient etching rate can be assured without hindering the high-frequency transfer and thermal conduction.

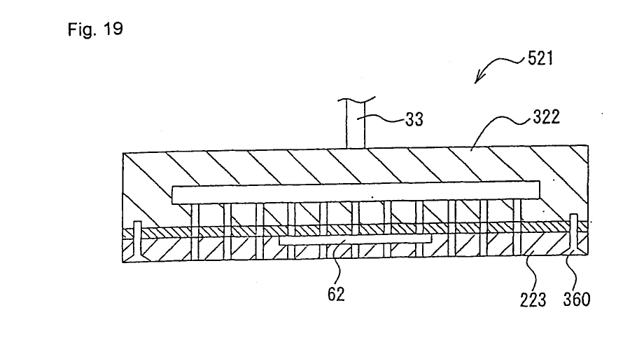

Also, the upper electrode 521 shown in FIG. 19 can be constituted, providing the hollow 62 pertaining to the first preferred embodiment in the electrode plate. This hollow 62 also may be provided on the side of the electrode supporting body. In either case, because fusion-adhesion of the material of the electrode plate on the electrode supporting body can be prevented and a uniform plasma also can be created, plasma processing of higher quality becomes possible.

Above, the preferred embodiments which are optimal for the plasma processing apparatus pertaining to the present invention, and the electrode plate, electrode supporting body, and shield ring thereof, were explained while referring to the attached drawings, but the present invention is not limited to such examples. It is clear that those who are skilled in this art can imagine various examples of modifications or amendments within the scope of the technical idea described in the claims, and it is understood that those naturally come within the technical scope of the present invention.

For example, the method of fabrication of the insulation film also may be by other methods such as CVD and PVD. Also, the material of the insulation film also may be other materials as long as they have excellent insulating property and erosion-resistance and can be made into a thin film.

### Possibility of Use in the Industry

The present invention relates to a plasma processing apparatus which performs processing on a body to be processed by introducing a processing gas into a vacuum processing chamber and creating a plasma thereof, and the electrode plate, electrode supporting body, and shield ring used therein, and it is particularly applicable to the process of fabrication of substrates for semiconductor equipment and a liquid crystal display, and the like.

1. A plasma processing apparatus comprising:
a processing chamber;
a first electrode on which a body to be processed can be placed inside said processing chamber;
a second electrode which is placed facing opposite said first electrode inside said processing chamber;
a processing gas supply system which is capable of supplying a processing gas into said processing chamber;
an exhaust system which is capable of vacuum-exhausting said processing chamber; and
a high-frequency electric power supply system which applies high-frequency electric power to at least one of said first and second electrodes to make said processing gas into a plasma and perform prescribed plasma processing on said body to be processed, wherein said second electrode comprises a supporting body and a conductive electrode plate having a first surface facing opposite said body to be processed;
said processing gas is supplied into said processing chamber via a gas inlet port, a space provided in said supporting body and a plurality of ejection holes arranged in said conductive electrode plate;
an insulation film is formed between said conductive electrode plate and said supporting body, and the insulation film is formed on the entire surface opposite to said first surface of said conductive electrode plate; and
a hollow portion for generating a uniform plasma is formed under said insulation film, said hollow portion is different from said space.

2. The plasma processing apparatus recited in claim 1 and characterized in that the thickness of said insulation film is less than or equal to 50 μm.

3. The plasma processing apparatus recited in claim 1 and characterized in that said supporting body consists of aluminum, and said electrode plate consists of silicon.

4. The plasma processing apparatus recited in claim 3 and characterized in that said insulation film is formed on said aluminum surface.

5. A supporting body characterized in that the supporting body is used in a plasma processing apparatus, comprising:
a processing chamber;
a first electrode on which a body to be processed can be placed inside said processing chamber;
a second electrode which is placed facing opposite said first electrode inside said processing chamber;
a processing gas supply system which is capable of supplying a processing gas into said processing chamber;
an exhaust system which is capable of vacuum-exhausting said processing chamber; and
a high-frequency electric power supply system which applies high-frequency electric power to at least one of said first and second electrodes to make said processing gas into a plasma and perform prescribed plasma processing on said body to be processed, wherein
said second electrode includes the supporting body and a conductive electrode plate having a first surface facing opposite said body to be processed;
said processing gas is supplied into said processing chamber via a gas inlet port, a space provided in said supporting body and a plurality of ejection holes arranged in said conductive electrode plate;
an insulation film is formed between said conductive electrode plate and said supporting body, and the insulation film is formed on the entire surface opposite to said first surface of said conductive electrode plate; and
a hollow portion for generating a uniform plasma is formed under said insulation film, said hollow portion is different from said space.

6. The supporting body recited in claim 5 and characterized in that said supporting body consists of aluminum.

7. The supporting body recited in claim 5 and characterized in that the insulation film on said aluminum surface is a rare-earth oxide or an aluminum compound.

8. An electrode plate characterized in that the electrode plate is used in a plasma processing apparatus, comprising:
a processing chamber;
a first electrode on which a body to be processed can be placed inside said processing chamber;
a second electrode which is placed facing opposite said first electrode inside said processing chamber;
a processing gas supply system which is capable of supplying a processing gas into said processing chamber;
an exhaust system which is capable of vacuum-exhausting said processing chamber; and
a high-frequency electric power supply system which applies high-frequency electric power to at least one of said first and second electrodes to make said processing gas into a plasma and perform prescribed plasma processing on said body to be processed, wherein
said second electrode includes a supporting body and the electrode plate, the electrode plate being conductive and having a first surface facing opposite said body to be processed;
said processing gas is supplied into said processing chamber via a gas inlet port, a space provided in said supporting body and a plurality of ejection holes arranged in said conductive electrode plate;
an insulation film for preventing fusion-adhesion of said supporting body and said electrode plate is formed on the entire surface opposite to said first surface of said conductive electrode plate; and
a hollow portion for generating a uniform plasma is formed under said insulation film, said hollow portion is different from said space.

9. The electrode plate recited in claim 8 and characterized in that said electrode plate is constituted with silicon.

10. The electrode plate recited in claim 9 and characterized in that the film for preventing fusion-adhesion of said supporting body and said electrode plate is a silicon compound.

11. A plasma processing apparatus comprising:
a processing chamber;
a first electrode on which a body to be processed can be placed inside said processing chamber;
a second electrode which is placed facing opposite said first electrode inside said processing chamber;
a processing gas supply system which is capable of supplying a processing gas into said processing chamber;
an exhaust system which is capable of vacuum-exhausting said processing chamber; and
a high-frequency electric power supply system which applies high-frequency electric power to at least one of said first and second electrodes to make said processing gas into a plasma and perform prescribed plasma processing on said body to be processed, wherein
said second electrode comprises a supporting body and a conductive electrode plate having a first surface facing opposite said body to be processed;
said processing gas is supplied into said processing chamber via a gas inlet port, a space provided in said supporting body and a plurality of ejection holes arranged in said conductive electrode plate;
an insulation film for preventing fusion-adhesion of said supporting body and said electrode plate is formed between said supporting body and said electrode plate, and the insulation film is formed on the entire surface opposite to said first surface of said conductive electrode plate; and
a hollow portion for generating a uniform plasma is formed under said insulation film, said hollow portion is different from said space.
